(19) United States
(12) Patent Application Publication
(10) Pub. No.: US 2017/0271285 A1
(43) Pub. Date: Sep. 21, 2017

(54) INTEGRATED CIRCUIT PACKAGE USING POLYMER-SOLDER BALL STRUCTURES AND FORMING METHODS

(71) Applicant: GLOBALFOUNDRIES INC., Grand Cayman (KY)

(72) Inventors: Richard S. Graf, Gray, ME (US); Kibby B. Horsford, Essex Junction, VT (US); Sudeep Mandal, Bangalore (IN)

(21) Appl. No.: 15/072,655

(22) Filed: Mar. 17, 2016

(51) Int. Cl. H01L 23/00

(52) U.S. Cl. CPC H01L 24/05; H01L 24/03; H01L 2224/0401; H01L 2224/0519; H01L 2224/05655; H01L 2224/05664; H01L 2224/03464; H01L 2224/0347; H01L 2224/03424; H01L 2224/0332

(57) ABSTRACT

A conductive polymer-solder ball structure is provided. The conductive polymer-solder ball structure includes a wafer having at least one metal pad providing an electrical conductive path to a substrate layer, a conductive polymer pad located directly on the wafer over the at least one metal pad, an electrolessly plated layer located on a surface of the conductive polymer pad, and a solder ball located on a surface of the electrolessly plated layer.

### FIELD OF THE INVENTION

The present disclosure relates generally to integrated circuits, and more specifically, to an integrated circuit package using polymer-solder ball structures and methods of forming the same.

### BACKGROUND OF THE INVENTION

Wafer-level chip-scale package (WLCSP) refers to a mechanism of packaging an integrated circuit (IC) at a wafer level, resulting in a device practically the same size as the die. An integrated circuit refers to a circuit in which a number of circuit elements are electrically connected on a single chip. Typically, integrated circuits are manufactured in large batches on a single semiconductor wafer. The large wafer contains an array of integrated circuits that is then cut such that each piece of the wafer contains a single copy of the integrated circuit. This individual copy of the integrated circuit on the wafer is known as a die. The process of cutting the large wafer into individual die is called device singulation. WLCSP provides a solder inter-connection directly between a device and an end product's motherboard.

WLCSP processing includes wafer bumping (with or without pad layer redistribution or redistribution layer (RDL)), wafer level final testing, device singulation, and packing in tape and reel. Wafer bumping refers to the process of forming solder balls on the wafer. A redistribution layer is a metal layer of the integrated circuit configured to enable contact with the input/output (I/O) pads of the integrated circuit at a different location. Device singulation, as explained above, refers to the process of cutting, dicing, or otherwise dividing an array of integrated circuits into individual integrated circuits. Some of the most widely offered WLCSP options include WLCSP bump on pad (BOP) and WLCSP with a redistribution layer (RDL).

The WLCSP bump on pad (BOP) option provides a reliable, cost-effective, true chip-size package on devices not requiring redistribution. Under-bump-metallurgy (UBM) is added and solder bumps are then placed directly over die I/O pads. WLCSP-BOP is designed to utilize industry-standard surface mount assembly and reflow techniques.

The WLCSP with a redistribution layer (RDL) option adds a plated copper RDL to route I/O pads to standard pitches such as those promulgated by the Joint Electron Device Engineering Council (JEDEC)/Electronic Industries Association of Japan (EIAJ) (JEDEC/EIAJ). Such monitoring avoids the need to redesign legacy parts for CSP applications. A nickel-based or thick copper UBM, along with polyimide or polybenzoxazole (PBO) dielectrics, provide improved board level reliability performance such as mechanical stability of the bump and reliable electronic connection between the solder bump and the I/O pad. WLCSP with RDL utilizes industry-standard surface mount assembly and reflow techniques, and does not require underfill on qualified device size and I/O layouts.

WLCSP has seen significant growth as a true chip scale package, by allowing direct chip attach of a flip chip die without underfill. WLCSP has also seen significant growth for mobile and smart phone applications, especially for power management IC's. However, WLCSP is restricted to systems having a relatively small die size and a low I/O count.

### BRIEF DESCRIPTION OF THE INVENTION

In one illustrative embodiment, a conductive polymer-solder ball structure is provided. The conductive polymer-solder ball structure includes a wafer having a substrate layer and at least one metal pad providing an electrically conductive path to the substrate layer; a conductive polymer pad located directly on the wafer over the at least one metal pad; an electrolessly plated layer over and contacting the conductive polymer pad; and a solder ball over and contacting the electrolessly plated layer.

In another illustrative embodiment, a method is provided for creating a conductive polymer-solder ball structure. The method includes forming at least one conductive polymer pad to a wafer, the wafer having at least one metal pad configured to provide an electrical conductive path to a substrate layer of the wafer; electrolessly plating a layer of conductive material to a surface of at least one of the at least one conductive polymer pads; and dropping a solder ball on at least one of the electrolessly plated layers.

In yet another illustrative embodiment, an integrated circuit package including one or more conductive polymer-solder ball structures is provided. Each conductive polymer-solder ball structure including a wafer having a substrate layer and at least one metal pad providing an electrical conductive path to the substrate layer; a conductive polymer pad located directly on the wafer over the at least one metal pad; an electrolessly plated layer located on a surface of the conductive polymer pad; and a solder ball located on a surface of the electrolessly plated layer.

### BRIEF DESCRIPTION OF THE DRAWINGS

The present disclosure, as well as the preferred mode of use and further objectives and advantages thereof, will best be understood by reference to the following detailed description of illustrative embodiments when read in conjunction with the accompanying drawings, wherein:

FIG. 1 depicts a cross-sectional view of processes in forming an integrated conductive polymer-solder base in accordance with an illustrative embodiment;

FIG. 2 depicts a cross-sectional view of processes in forming an integrated conductive polymer-solder base in accordance with an illustrative embodiment;

FIG. 3 depicts a cross-sectional view of processes in forming an integrated conductive polymer-solder base in accordance with an illustrative embodiment;

FIG. 4 depicts a cross-sectional view of processes in forming an integrated conductive polymer-solder base in accordance with an illustrative embodiment;

FIGS. 5 and 6 depict cross-sectional views of processes in forming a solder ball on top of the integrated conductive polymer-solder base illustrated in FIGS. 1-4 utilizing a ball drop option in accordance with an illustrative embodiment;

FIG. 7 depicts a cross-sectional view of processes in creating an integrated conductive polymer-solder base in accordance with an illustrative embodiment;

FIG. 8 depicts a cross-sectional view of processes in creating an integrated conductive polymer-solder base in accordance with an illustrative embodiment;

FIG. 9 depicts a cross-sectional view of processes in creating an integrated conductive polymer-solder base in accordance with an illustrative embodiment;

FIG. 10 depicts a cross-sectional view of processes in creating an integrated conductive polymer-solder base in accordance with an illustrative embodiment; and

FIGS. 11 and 12 depict cross-sectional views of processes in forming a solder ball on top of the integrated conductive polymer-solder base illustrated in FIGS. 7-10 utilizing a ball drop option is accordance with an illustrative embodiment.

These and other features and advantages of the present disclosure will be described in, or will become apparent to those of ordinary skill in the art in view of, the following detailed description.

### DETAILED DESCRIPTION OF THE INVENTION

As stated previously, wafer-level chip-scale packaging (WLCSP) refers to a technology of packaging an integrated circuit at a wafer level, resulting in a device practically the same size as the die. However, current WLCSP is constrained by two major factors: chip size and bump pitch/density. With regard to chip size, WLCSP requires that all bumps must be contained within the chip footprint, and it is not economically feasible to grow chip size in order to increase the number of bumps. With regard to bump pitch/density, reducing the bump size/pitch increases bump density, but reducing the size of the bump also reduces the reliability. While redistribution layers may be added to relocate the bumps to a location other than the location of I/O pads, the redistribution layers also causes a significant cost increase. Illustrative embodiments provide a screen printed conductive polymer base for a WLCSP solder bump, which improves reliability as well as enables larger chip sizes to utilize the WLCSP solution without the need to add an additional redistribution layer to the wafer.

The present description and claims may make use of the terms “a,” “at least one of,” and “one or more of” with regard to particular features and elements of the illustrative embodiments. It should be appreciated that these terms and phrases are intended to state that there is at least one of the particular feature or element present in the particular illustrative embodiment, but that more than one can also be present. That is, these terms/phrases are not intended to limit the description or claims to a single feature/element being present or require that a plurality of such features/elements be present. To the contrary, these terms/phrases only require at least a single feature/element with the possibility of a plurality of such features/elements being within the scope of the description and claims.

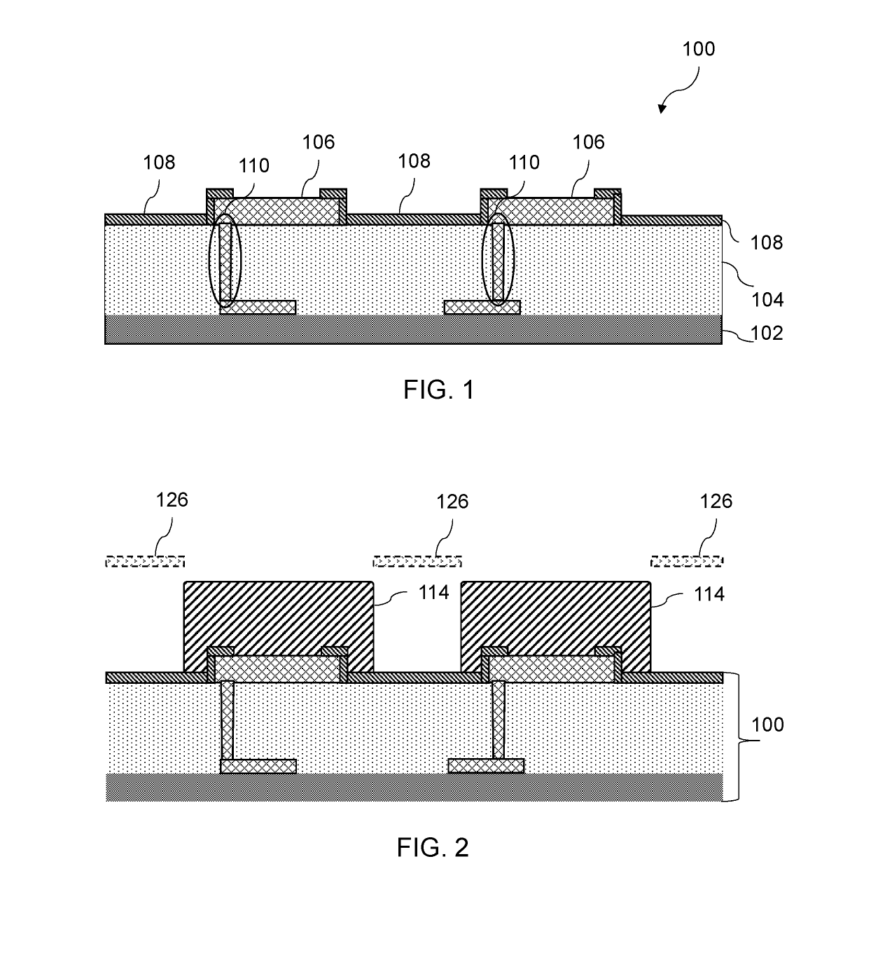

FIGS. 1-4 depict cross-sectional views of processes of creating a conductive polymer-solder base in accordance with an illustrative embodiment. Initially, as shown in FIG. 1, a bare wafer structure 100 is constructed to include a substrate layer 102, a dielectric layer 104, one or more metal pad structures 106 applied to dielectric layer 104 at locations on wafer structure 100 where one or more solder ball structures will be formed. Dielectric layer 104 may include an oxide dielectric material, or any other dielectric material now known or later developed.

A dielectric is a non-conducting-material or substance. (A dielectric is an electrical insulator.) Some dielectrics commonly used in semiconductor technology are SiO₂ (silicon dioxide or “oxide”) and Si₃N₄ (silicon nitride or “nitride”).

Metal pad structures 106 may include aluminum, gold, copper, or any other electrically conductive metal or combinations of metals now known or later developed. Wafer structure 100 also includes a passivation dielectric layer 108 applied to the other locations on wafer structure 100 where the one or more solder ball structures will not be formed. Passivation dielectric layer 108 may include a hard oxide material, nitride, or any other dielectric material now know or later developed.

Dielectric layer 104 includes chip back end of line (BEOL) features. BEOL refers to operations performed on the semiconductor wafer in the course of device manufacturing following first metallization. Dielectric layer 104 may potentially include numerous metal layers and passivation layers as well as a low-k dielectric, which is a material with a small dielectric constant relative to silicon dioxide. As is illustrated, metal pad structures 106 may be electrically connected to any layer between metal pad 106 and substrate 102 using vias 110. As is further illustrated, passivation dielectric layer 108 may also be applied to outer portions of one or more metal pad structures 106 in order to provide structural support for metal pad structures 106.

As is illustrated in FIG. 2, a stencil 126 may be used to mask off areas where one or more solder ball structures will be formed. With the stencil applied, one or more conductive polymer pad structures 114 are formed via screen printing directly onto wafer structure 100 at locations where one or more solder ball structures will be formed. Conductive polymer pad structures 114 are typically a B-stage polymer or a thermoplastic polymer, which is filled with electrically conductive particles, such as silver, gold, copper, or nickel, or filled with electrically conductive particles consisting of a polymer core with nickel plating or gold plating.

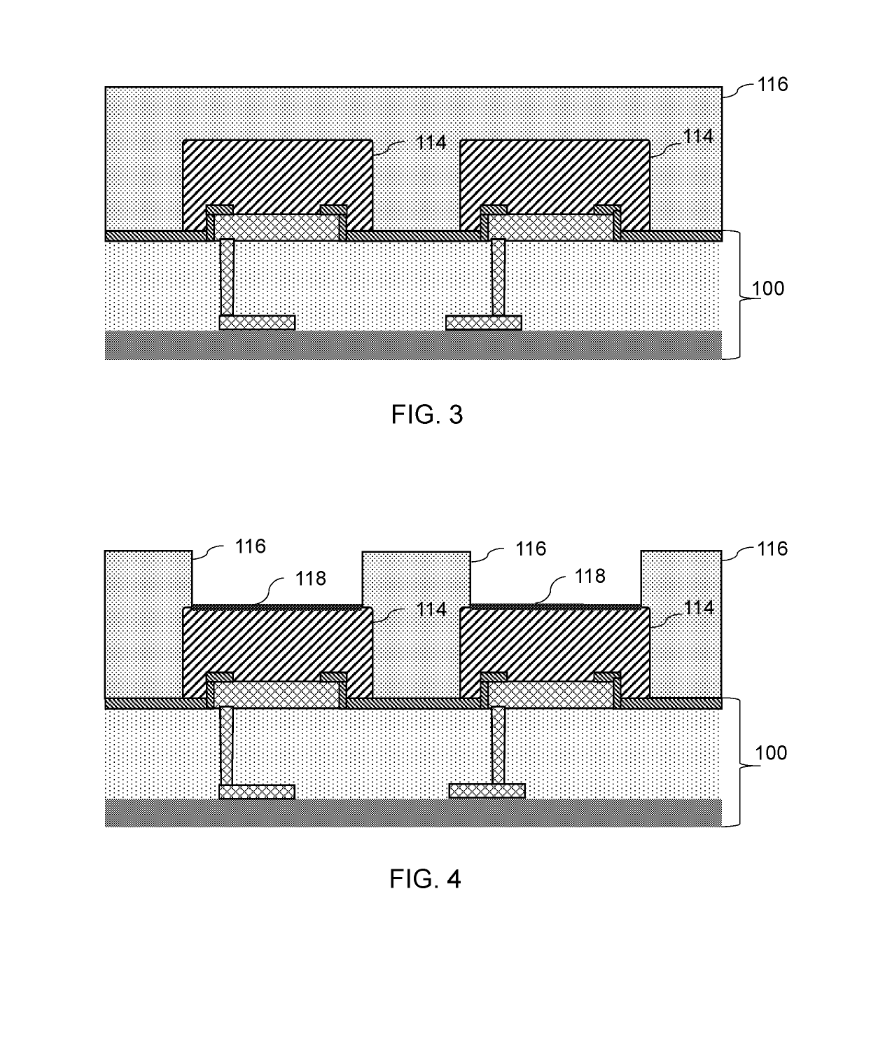

As illustrated in FIG. 3, a photoresist layer 116 may be applied on top of the exposed portions of wafer structure 100 and one or more conductive polymer pad structures 114. Portions of one or more conductive polymer pad structures 114 may be subsequently exposed (after applying photoresist layer 116), as shown in FIG. 4. Also shown in FIG. 4, once the portions of one or more conductive polymer pad structures 114 are exposed, an electrolessly plated layer 118 of conducive material is applied to the exposed portions of one or more conductive polymer pad structures 114. In accordance with one illustrative embodiment, electrolessly plated layer 118, i.e., the conductive material, may be a layer of electroless nickel immersion gold (ENIG), electroless nickel electroless palladium immersion gold (ENEPIG), nickel-phosphorous, nickel-boron, or other combination of these materials or another electroless plating material used to interface between one or more conductive polymer pad structures 114 and one or more solder ball structures, and gold.

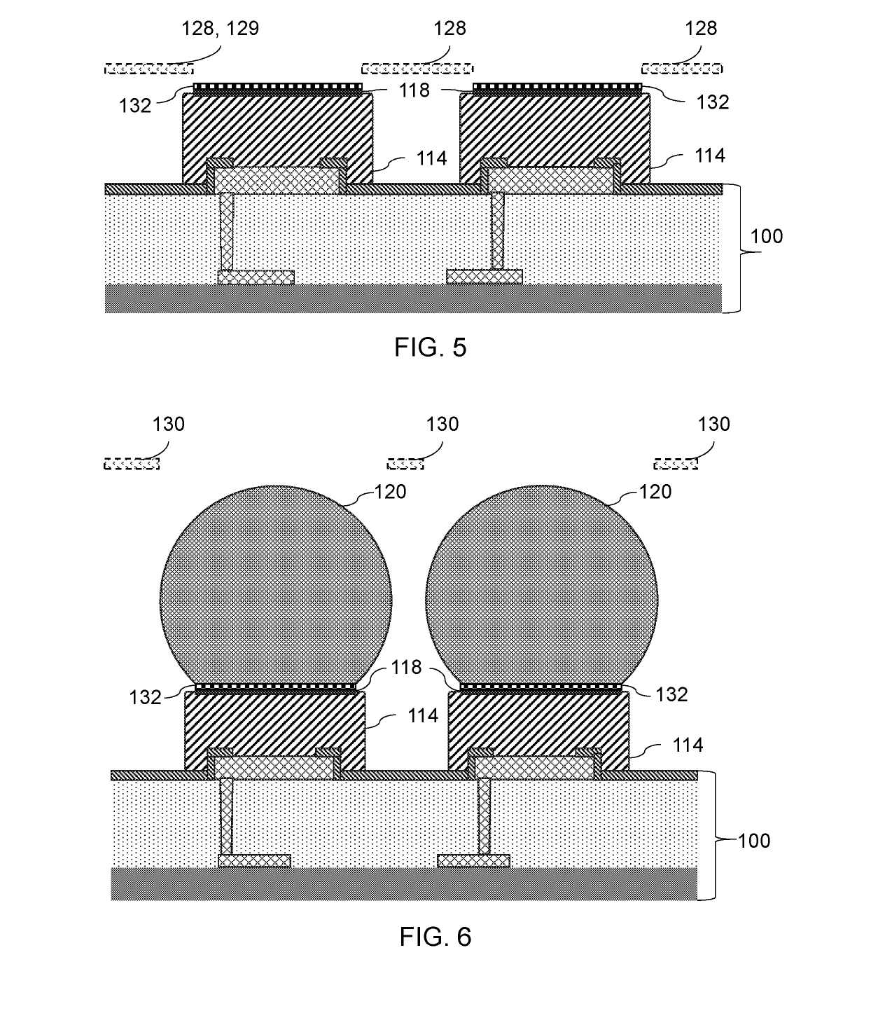

FIGS. 5 and 6 depict cross sectional views of processes in forming a solder ball 120 (FIG. 6) on top of the integrated conductive polymer-solder base illustrated in FIGS. 1-4 utilizing a ball drop option in accordance with an illustrative embodiment. Prior to this process, any remaining portions of photoresist layer 116 are removed, e.g., by etching. As is illustrated in FIG. 5, a first temporary stencil 128 is used to apply flux to electrolessly plated layer 118. That is, a first stencil 128 is applied to the wafer and flux is screen printed through the first stencil to apply the flux to electrolessly plated layer 118. Once flux has been applied, first stencil 128 is removed and then a second stencil 130 (FIG. 6) is applied to facilitate solder ball placement on electroless plating later 118, which now has flux on its surface. As is shown in FIG. 6, a ball of solder (solder ball) 120 is then placed into second stencil 130 openings on each associated electrolessly plated layer 118 by dropping the solder through second stencil 130 onto the associated electrolessly plated layer 118. Second stencil 130 is removed and ball of solder 120 is reflowed by heating ball of solder 120 to a predetermined temperature, such as between approximately 200° F.-300° F., in order to form one or more solder ball structures and join ball of solder 120 to electrolessly plated layer 118. “Approximately” as used herein indicates +/−10% of the value(s) stated. In one embodiment, solder ball 120 is heated to approximately 260° F. Each of the one or more balls of solder 120 may include tin, lead, silver, copper, bismuth, gold, nickel, or combinations of these materials.

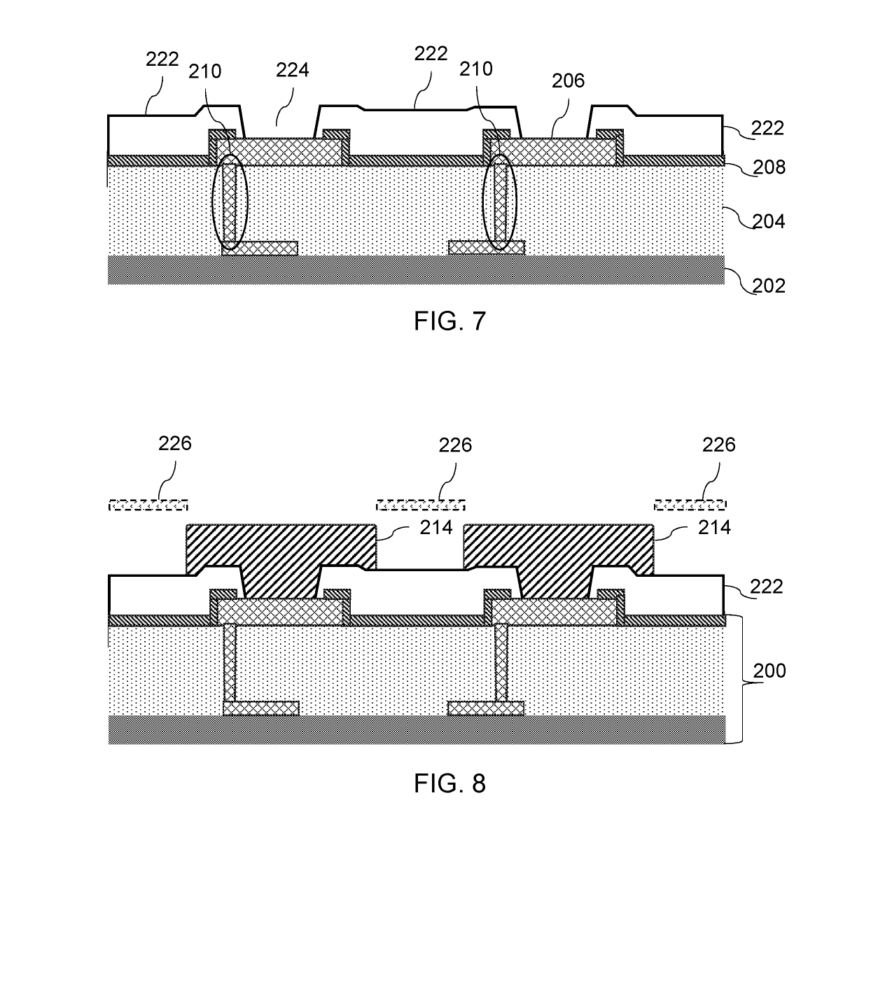

FIGS. 7-10 depict cross-sectional views of processes in creating an integrated polymer-solder base in accordance with an illustrative embodiment. Initially, as shown in FIG. 7, a wafer structure 200 is constructed in accordance with the above description of FIG. 1. Similar to the above description of wafer structure 100, wafer structure 200 includes substrate layer 202, dielectric layer 204, metal pad structures 206, and passivation dielectric layer 208. In an illustrative embodiment, as shown in FIG. 7, a polyimide coating 222 is applied to wafer structure 200 and openings 224 are formed in polyimide coating 222 (e.g., by etching or patterned formation of the polyimide) where one or more solder ball structures will be formed.

As is illustrated in FIG. 8, a stencil 226 is used to mask-off areas where one or more solder ball structures will be formed. With stencil 226 applied, one or more conductive polymer pad structures 214 are formed via screen printing directly on top of wafer structure 200 and polyimide coating 222 at locations on wafer structure 200 where one or more solder ball structures will be formed. Conductive polymer pad structures are typically B-stage polymer or a thermoplastic polymer, which is filled with electrically conductive particles, such as silver, gold, copper, or nickel, or filled with electrically conductive particles consisting of a polymer core with nickel plating or gold plating.

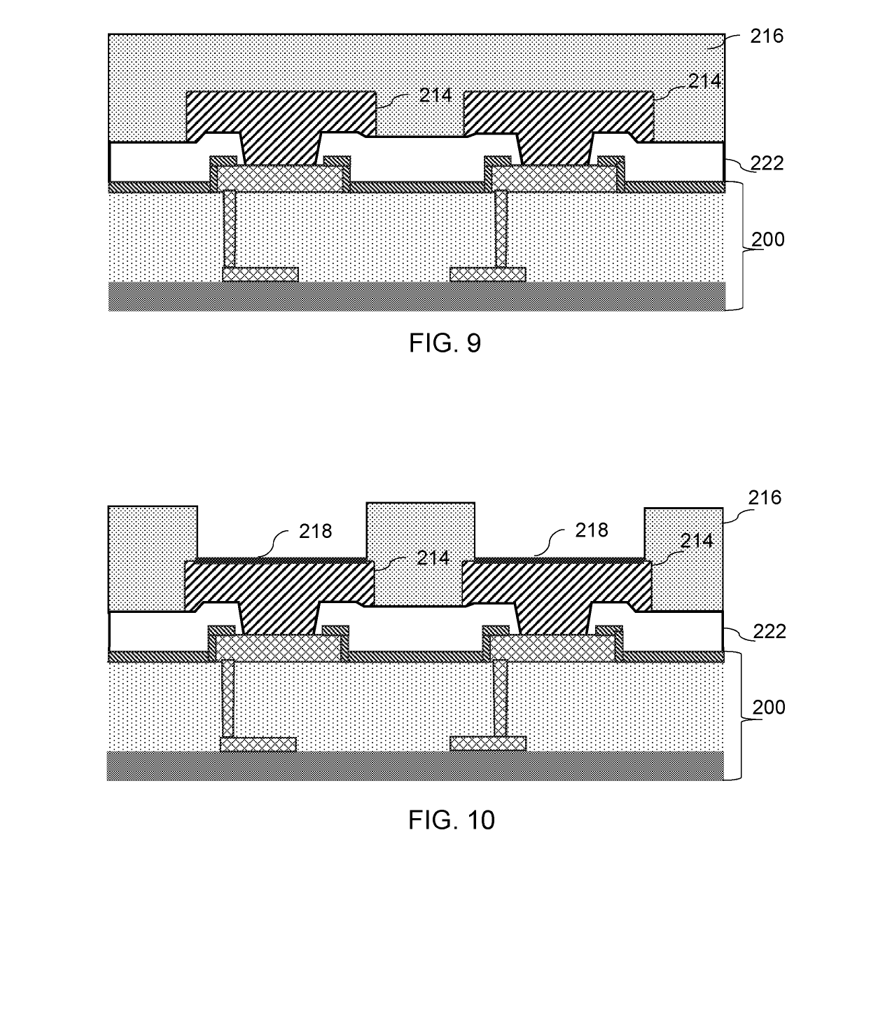

As is illustrated in FIG. 9, a photoresist layer 216 may be applied on top of the exposed portions of polyimide coating 222 and one or more conductive polymer pad structures 214. Portions of one or more conductive polymer pad structures 214 may be exposed, as shown in FIG. 10, by patterning photoresist layer 216 and etching. As is illustrated in FIG. 10, once the intended portions of one or more conductive polymer pad structures 214 are exposed, an electrolessly plated layer 218 of conductive material is applied to the exposed portions of one or more conductive polymer pad structures 214. In accordance with one illustrative embodiment, electrolessly plated layer 218, i.e., conductive material, may be a layer of electroless nickel immersion gold (ENIG), electroless nickel electroless palladium immersion gold (ENEPIG), nickel-phosphorous, nickel-boron or other combination of these materials or another electroless plating material used to interface between one or more conductive polymer pad structures 214 and one or more solder ball structures, and gold.

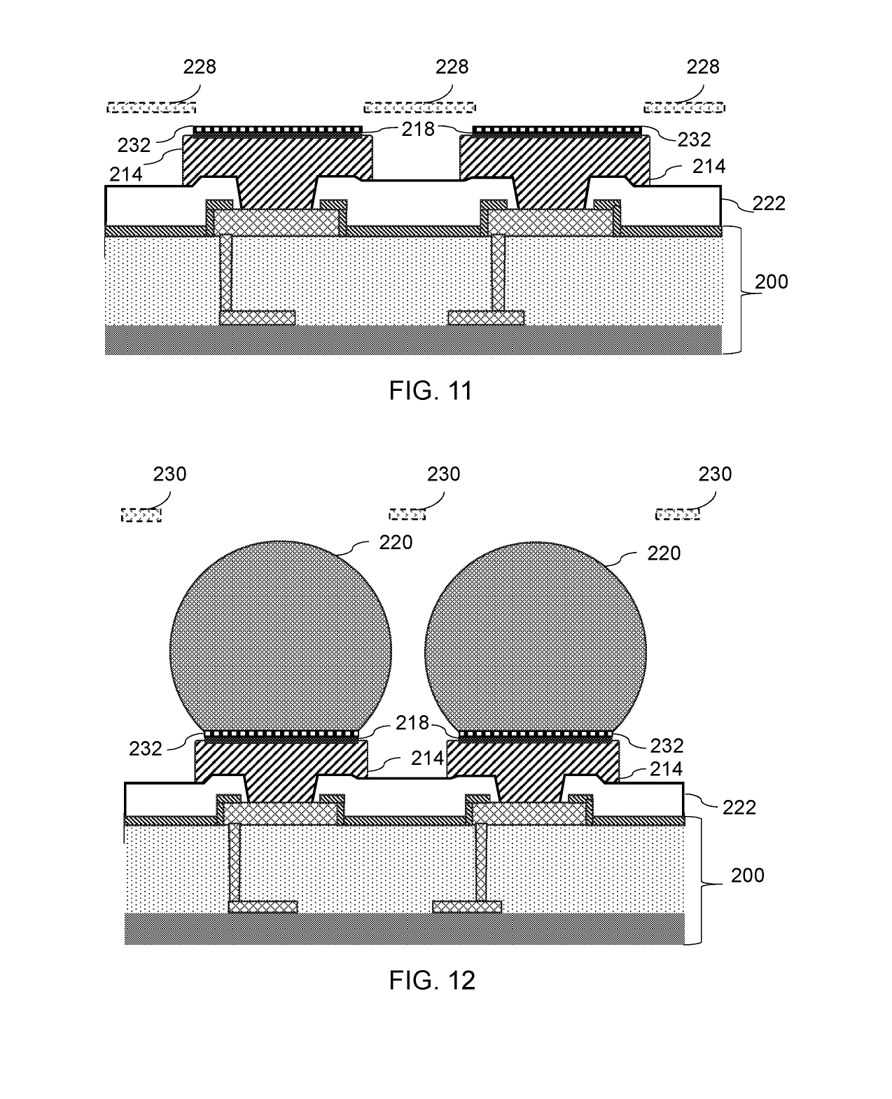

FIGS. 11 and 12 depict cross-sectional views of forming a solder ball on top of the integrated conductive polymer-solder base illustrated in FIGS. 7-10 utilizing a ball drop option in accordance with an illustrative embodiment. Prior to this process, any remaining portions of photoresist layer 216 are removed, e.g., by etching. As is illustrated in FIG. 11, a temporary stencil 228 is used to apply flux to electrolessly plated layer 218. That is, a first stencil 228 is applied to the wafer and flux 232 is screen printed through first stencil 228 to apply the flux to electrolessly plated layer 218. Once flux 232 has been applied, first stencil 228 is removed and then a second stencil 230 (FIG. 12) is applied to facilitate solder ball placement on electroless plating later 218, which now has flux 232 on its surface. As is shown in FIG. 12, a ball of solder 220 is then placed into the stencil openings on each associated electrolessly plated layer 218 by dropping the solder through second stencil 230 onto the associated electrolessly plated layer 218. Second stencil 230 is removed and ball of solder 220 is reflowed by heating ball of solder 220 to a predetermined temperature, such as between approximately 200° F.-300° F., in order to form one or more solder ball structures and join ball of solder 220 to electrolessly plated layer 218. In one exemplary embodiment, solder ball 220 is heated to approximately 260° F. Each of the one or more balls of solder 220 may include tin, lead, silver, copper, bismuth, gold, nickel, or combinations of these materials.

Thus, the illustrative embodiments provide for a screen-printed conductive polymer base for a WLCSP solder bump 120, 220, which improves reliability as well as enables larger chip sizes to utilize the WLCSP solution without the need to add an additional redistribution layer to the wafer. One or more conductive polymer pads are applied to a wafer structure at locations on the wafer structure where one or more solder ball structures will be formed. Portions of the one or more conductive polymer pad structures are masked off and a photoresist layer 116, 216 is applied to the wafer. Then, the portions of the one or more conductive polymer pad structures that were masked off are opened up to expose the top of one or more conductive polymer pad structures 114, 214 and an electroless plating later 118, 218 is applied to the exposed portions of the one or more conductive polymer pad structures. Finally, a solder ball 120, 220 is formed on each of the electrolessly plated layers thereby forming the one or more solder ball structures. Creating a screen printed conductive polymer base for a WLCSP in this way lowers the cost as compared to a double redistribution layer method while improving reliability. The illustrated process also allows for growth of chip size or reduction of WLCSP bump size/pitch. For WLCSP to be joined to next level assembly, the wafer must be thinned and each chip must be diced out.

The present disclosure is presented for purposed of illustration and description, and is not intended to be exhaustive or limited to the invention in the form disclosed. Many modifications and variations will be apparent to those of ordinary skill in the art without departing from the scope and spirit of the described embodiments. The embodiments were chosen and described in order to best explain the principles of the present disclosure, the practical application, and to enable others of ordinary skill in the art to understand the present disclosure for various embodiments with various modifications as are suited to the particular use contemplated. The terminology used herein was chosen to best explain the principles of the embodiments, the practical application or technical improvement over technologies found in the marketplace, or to enable others of ordinary skill in the art to understand the embodiments disclosed herein.

1. A conductive polymer-solder ball structure for an integrated circuit package, the structure comprising:
a wafer having a substrate layer and at least one metal pad providing an electrically conductive path to the substrate layer;
a conductive polymer pad located directly on the wafer over the at least one metal pad;
an electrolessly plated layer on only the conductive polymer pad, and contacting the conductive polymer pad; and
a solder ball over and contacting the electrolessly plated layer.

2. The conductive polymer-solder ball structure of claim 1, wherein the electrolessly plated layer includes electroless nickel immersion gold (ENIG).

3. The conductive polymer-solder ball structure of claim 1, wherein the electrolessly plated layer includes electroless nickel electroless palladium immersion gold (ENEPIG).

4. The conductive polymer-solder ball structure of claim 1, further comprising a polyimide coating located on a surface of the wafer, the polyimide coating having an opening at each location of the at least one metal pad.

5. The conductive polymer-solder ball structure of claim 1, wherein the conductive polymer pad is directly attached to the metal pad.

6. The conductive polymer-solder ball structure of claim 1, wherein the electrolessly plated layer is directly attached to the conductive polymer pad.

7-14. (canceled)

15. An integrated circuit package having at least one conductive polymer-solder ball structure, each conductive polymer-solder ball structure comprising:
a wafer having a substrate layer and at least one metal pad providing an electrical conductive path to the substrate layer;
a conductive polymer pad located directly on the wafer over the at least one metal pad;
an electrolessly plated layer located only on a surface of the conductive polymer pad; and
a solder ball located on a surface of the electrolessly plated layer.

16. The integrated circuit package of claim 15, wherein the electrolessly plated layer includes electroless nickel immersion gold (ENIG).

17. The integrated circuit package of claim 15, wherein the electrolessly plated layer includes electroless nickel electroless palladium immersion gold (ENEPIG).

18. The integrated circuit package of claim 15, each integrated conductive polymer-solder ball structure further comprising a polyimide coating located on a surface of the wafer, the polyimide coating having openings at the location of the at least one metal pad.

19. The integrated circuit package of claim 15, wherein the conductive polymer pad is directly attached to the metal pad.

20. The integrated circuit package of claim 15, wherein the electrolessly plated layer is directly attached to the conductive polymer pad.

21. The conductive polymer-solder ball structure of claim 1, wherein the solder ball is located directly over the conductive polymer pad.

22. The conductive polymer-solder ball structure of claim 1, wherein solder ball is located directly over the metal pad.

23. The conductive polymer-solder ball structure of claim 1, further comprising a passivation layer located partially on the metal pad.

24. The conductive polymer-solder ball structure of claim 23, wherein a portion of the passivation layer is located between the metal pad and the conductive polymer pad.

25. The integrated circuit package of claim 15, wherein the solder ball is located directly over the conductive polymer pad.

26. The integrated circuit package of claim 15, wherein solder ball is located directly over the metal pad.

27. The integrated circuit package of claim 15, further comprising a passivation layer located partially on the metal pad.

26. The integrated circuit package of claim 27, wherein a portion of the passivation layer is located between the metal pad and the conductive polymer pad.
